(19) United States
(12) Patent Application Publication
(10) Pub. No.: US 2026/0209931 A1
(43) Pub. Date: Jul. 23, 2026

(54) DEEP BLACK DECORATIVE COATING WITH INCREASED THERMAL STABILITY

(71) Applicant: Oerlikon Surface Solutions AG, Pfäffikon, Pfäffikon (CH)

(72) Inventor: Julien KERAUDY, Buchs (CH)

(21) Appl. No.: 19/142,366

(22) PCT Filed: Dec. 21, 2023
(86) PCT No.: PCT/EP2023/087347

§ 371 Date: Jun. 23, 2025

(30) Foreign Application Priority Data
Dec. 23, 2022 (DE) 10 2022 004 910.4

(51) Int. Cl. C23C 14/35; C23C 14/02; C23C 14/06; C23C 14/18

(52) U.S. Cl. CPC C23C 14/35; C23C 14/021; C23C 14/025; C23C 14/0611; C23C 14/0676; C23C 14/18

(57) ABSTRACT

The present invention relates to a coating that includes at least an optically absorbing metal oxide and/or oxynitride deep black layer deposited directly onto the surface of the part to be coated. In another embodiment, the deep black layer is deposited on a metallic adhesion-promoting layer, followed by a hard and optically transparent oxynitride layer. The foregoing coatings may be deposited by a reactive magnetron sputtering method and exhibit enhanced thermal stability at temperatures above 400° C.

### FIELD OF THE INVENTION

The present invention relates to a deep black coating that demonstrates enhanced thermal stability at high temperatures.

### BACKGROUND OF INVENTION

Recently, coatings with a decorative deep black appearance, also known as deep black, continue to be a highly popular coating color for decorative purposes, especially in the field of consumer articles, such as jewelry, watches, mobile phones, sanitary fixtures and medical applications. According to the International Commission on Illumination (CIE) Standard CIE 1976 L*a*b* color space, surfaces are considered as deep black surfaces if they exhibit L*<40, most preferably L*<35 with a/b values near 0, where L* values stand for perceptual lightness and a* and b* for colors of human vision. The CIE 1976 L*a*b* color space which is based on D 65 standard lighting and a d/8° (=diffuse lighting and measurement at under 8°) is taken as a basis.

In addition to the aesthetic appeal of these coatings, these decorative coatings feature additional functional properties, such as high hardness, enhanced wear resistance against scratches and abrasive wear and resistance against chemicals and corrosion.

German application no. DE3639469A1 describes a hard material layer with a decorative black appearance, which simultaneously has a high wear resistance. This hard material layer includes a first layer composed of an element from Groups IVa and Va of the periodic table of elements, a second layer that includes a nitride of this element of the first layer, a third layer that contains a carbide of the element, and a covering layer composed of a hard carbon layer, with carbide crystallites of the same element being embedded in this covering layer.

It is also known to use diamond-like carbon (DLC) layers that have a black appearance and a high degree of hardness. However, conventional DLC layers have neutral gray values expressed by the lightness L* that lie in the range above 40.

US Patent Application Publication No. 2016/0002792A1 describes a method for producing a wear-resistant layer for decorative application with a deep black appearance. This hard material layer includes a diamond-like carbon (DLC) layer with a hardness of at least 10 GPa and a refractive index n_{DLC} of n_{DLC}>2.1. A separate gradient layer is disposed on top of the DLC layer, wherein the gradient layer is at least 300 nm thick. This gradient layer has a decreasing density and therefore a decreasing refractive index. This results in a refraction index gradient, wherein an average fraction index along 30 nm adjacent to an interface with the DLC layer, is greater than or equal to 2.0 and wherein an averaged refraction index of the gradient layer determined as an average along 30 nm adjacent to an outer surface opposite the DLC layer, does not exceed 1.85. By means of the refraction index progression that this produces in the gradient layer, the gradient layer functions as a reflection-reducing layer. The chemical composition of the gradient layer differs from a chemical composition of the DLC layer essentially only with regard to hydrogen content.

US Patent Application Publication No. 2016/0053371A1 describes a decorative article that includes a base and a black hard coating film which is formed on the base, and which comprises diamond-like carbon (DLC) wherein a hydrogen content of a surface of the black hard coating film that is spaced from the base is higher than a hydrogen content of a surface of the black hard coating film that is closer to the base. The hydrogen content of the surface of the black hard coating film that is spaced from the base is 30.0 to 70.0 at. %. The article having the coating film is a timepiece, a necklace, a pendant, a brooch, or glasses. The black hard coating film comprises a gradient layer comprising diamond-like carbon. A hydrogen content in the gradient layer increases in a direction away from the base. Similarly to US 20160002792A1, by means of the gradient of hydrogen content the gradient layer functions as a reflection-reducing layer.

The foregoing coatings utilize DLC-layers. It is known that one disadvantage of DLC-layers is that they tend to be thermally stable up to about 350° C. and start to graphitize at higher temperature. When heated to these temperatures the DLC-layers experience irreversible changes in their optical and mechanical properties. It is desirable, in certain applications, that components coated with decorative coatings be able to withstand exposure to temperatures above 400° C. without the optical properties of the coating being altered to such a degree that a change in the coating color can be visually detected.

The present application provides a hard and deep black appearance coating that experiences little or no change in optical properties at high temperatures.

### SUMMARY OF THE INVENTION

There is provided a coating deposited on substrate. The coating including a multilayer design approach comprising at least an optically absorbing deep black gradient layer deposited directly onto the surface of the part to be coated or on a metallic adhesion-promoting layer, followed by the deposition on a top of a hard and optically transparent layer. Hard layer in this context means a layer exhibiting a coating hardness above 15 GPa. Optically transparent in this context means that the material has a high transmission coefficient (close to 100%) for light with energies in the IR, visible and UV wavelength ranges.

The foregoing coating further including a deep black layer that can be either metal oxide and/or oxynitride.

The foregoing coating, wherein the deep black metal oxide and/or oxynitride layer have L*<40.

The foregoing coating wherein the deep black metal oxide and/or oxynitride layer includes one or more metals or one or more rare earth metals or one or more metalloids or one or more alkaline earth metals.

The foregoing coating wherein the one or more metals includes Al, Ti, Cr, Ni, Nb, V, Fe, Mo, Ta, W or Hf or the one or more rare earth metals includes Y, Ce, Gd or Er or the one or more metalloids includes Si, C or B or the one or more alkaline earth metals includes Mg, Ca, Sr or Be.

The foregoing coating wherein the deep black metal oxide and/or oxynitride layer includes a decreasing concentration of metal and an increasing concentration of oxygen or a combination of oxygen and nitrogen as measured from the substrate.

The foregoing coating wherein deep black metal oxide and/or oxynitride layer is Me₁₋ₓRₓ where 0.05<x<0.5 and R is a non-metallic element that includes oxygen and/or a combination of oxygen and nitrogen.

The foregoing coating wherein in the deep black oxynitride layer a ratio of oxygen to nitrogen is fixed and is 0.4 or above.

The foregoing coating wherein the deep black metal oxide and/or oxynitride layer has a thickness greater than 0.1 μm.

The foregoing coating wherein the deep black metal oxide and/or oxynitride layer has a thickness greater than 0.3 μm.

The foregoing coating wherein the deep black metal oxide and/or oxynitride layer has a thickness greater than 0.5 μm.

The foregoing coating further including an optically transparent oxynitride layer that is deposited on the deep black metal oxide and/or oxynitride layer.

The foregoing coating wherein the optically transparent oxynitride layer includes one or more metals or one or more rare earth metals or one or more metalloids or one or more alkaline earth metals.

The foregoing coating wherein the one or more metals includes Al, Ti, Cr, Ni, Nb, V, Fe, Mo, Ta, W or Hf or the one or more rare earth metals includes Y, Ce, Gd or Er or the one or more metalloids includes Si, C or B or the one or more alkaline earth metals includes Mg, Ca, Sr or Be.

The foregoing coating wherein the optically transparent oxynitride layer is a monolithic layer having a content of metal that is between 0.4 to 0.5, a content of oxygen that is between 0.05 to 0.1 and a content of nitrogen that is between 0.4 to 0.45.

The foregoing coating wherein the optically transparent oxynitride layer has a thickness greater than 0.3 μm.

The foregoing coating wherein the optically transparent oxynitride layer has a thickness greater than 0.5 μm.

The foregoing coating wherein the optically transparent oxynitride layer has a thickness greater than 1.0 μm.

The foregoing coating wherein the optically transparent oxynitride layer has a hardness that is greater than 12 Gpa.

The foregoing coating, wherein the optically transparent oxynitride layer has a hardness that is greater than 15 Gpa.

The foregoing coating wherein the optically transparent oxynitride layer has a hardness that is greater than 20 GPa.

The foregoing coating wherein the metallic-adhesion promoting layer a thickness greater than 0.3 μm.

The foregoing coating, wherein the metallic element is similar to the one use for the deep black metal oxide and/or oxynitride layer and optically transparent oxynitride layer.

There is also provided a process of depositing a coating on a substrate. The process includes steps of implementing a closed loop control of a reactive gas in a coating chamber to deposit a deep black metal oxide and/or oxynitride layer directly onto the substrate or as the case may be adhesion promotion means such as for example a metallic adhesion promoting layer; and maintaining conditions achieved during the foregoing step for a predetermined period of time to deposit an optically transparent oxynitride layer on the deep black metal oxide and/or oxynitride layer.

In the foregoing process, prior to the step of implementing, steps of solvent cleaning the substrate; placing the substrate in a coating chamber; evacuating the coating chamber; plasma etching the substrate; and exposing the substrate to bipolar power to create an adhesion layer on the substrate.

### BRIEF DESCRIPTION OF THE DRAWINGS

FIG. 1 provides a schematic view of a coating chamber that may be used for the present invention. FIG. 2 illustrates the color characteristics for an AlON-based layer containing a metal-based adhesion layer and an optically absorbing deep black layer, according to one embodiment of the present invention;

FIG. 3 illustrates the color characteristics for an AlON-based coating that contains a metal-based adhesion layer, an optically absorbing deep black layer and a hard and optically transparent layer, according to a second embodiment of the present invention;

FIG. 4 provides a comparison of a deep black coating according to the present invention and a deep black coating of the prior art and illustrates a change in the respective coatings after annealing in air for 24 hours at 500° C.; and

FIG. 5 provides a comparison of a deep black coating according to the present invention and a deep black coating of the prior art and graphically illustrates the hardness of the coatings as a function of annealing temperature.

### DETAILED DESCRIPTION OF PREFERRED EMBODIMENT

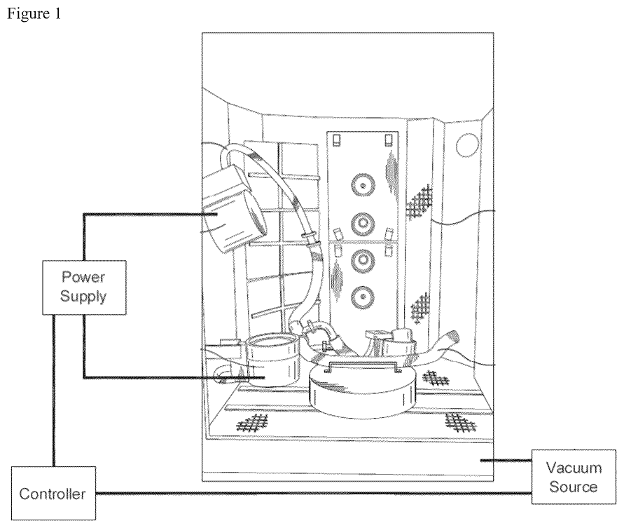

The present invention may provide a method for depositing a multilayer coating that includes an optically absorbing deep black layer 20 deposited directly onto a substrate 10 to be coated, see, FIG. 2. Referring to FIG. 1, a schematic of a coating chamber is illustrated. The coating chamber may be used to apply the optically absorbing deep black layer 20 to the substrate 20.

Referring to FIG. 2, the optically absorbing deep black layer 20 may include, but not be limited to, metal oxides (M-O) or oxynitrides (M-O-N). It is contemplated that the optically absorbing deep black layer 20 may include a single metal element, or a complex metal oxide including a mixture of multiple metals. In some embodiments, the optically absorbing deep black layer 20 may include a two-metal composition (M1ₓM2_{y}O_{z}), a three-metal composition (M1_{w}M2ₓM3_{y}O_{z}), a four-metal composition (M1ᵥM2_{w}M3ₓM4_{y}O_{z}), a five-metal composition (M1ᵤM2ᵥM3_{w}M4ₓM5_{y}O_{z}), etc. In each of the foregoing optically absorbing deep black layers 20, the variables u, v, w, x, y, z may be positive integers or decimal values. Some example values of u, v, w, x, y, z may range from about 0.02 to about 1.0.

In an alternative embodiment, it is contemplated that the optically absorbing metal oxide deep black layer 20 may include one or more metals including, but not limited to, Al, Ti, Cr, Ni, Nb, V, Fe, Mo, Ta, W, Hf, and/or one or more rare earth metals, such as Y, Ce, Gd, Er and/or one or more of another metalloids, such as Si, C, B and/or one or more of alkaline earth metals, such as Mg, Ca, Sr, Be. In some embodiments, the optically absorbing deep black layer 20 may be, Al—O, Al—Si—O, Al—Cr—O, Al—Ti—O—N, Al—Mg—O, Al—Ca—O, Al—Mn—O, Al—Zn—O, Al—Ta—O, Al—W—O, Al—Mo—O, Al—Mn—O, Si—O, Si—Mg—O, Si—Ca—O, Ti—O, Nb—Ti—O, Ti—Mg—O, Ti—Ca—O, Ni—O, Ni—Ca—O, Ni—Mg—O.

In an alternative embodiment, the optically absorbing deep black layer 20 may include a single metal element, or a complex metal oxynitride including a mixture of multiple metals. In some embodiments, the optically absorbing deep black layer 20 may include a two-metal composition (M1_{w}M2ₓO_{y}N_{z}), a three-metal composition (M1ᵥM2_{w}M3ₓO_{y}N_{z}), a four-metal composition (M1ᵤM2ᵥM3_{w}M4ₓO_{y}N_{z}), a five-metal composition (M1ₜM2ᵤM3ᵥM4_{w}M5ₓO_{y}N_{z}), etc. In each of the foregoing optically absorbing deep black layers 20, the variables t, v, w, X, y, z may be positive integers or decimal values. Some example values of t, v, w, x, y, z may range from about 0.05 to about 0.6.

In one embodiment, the optically absorbing metal oxide deep black layer 20 may include one or more metals including, but not limited to, Al, Ti, Cr, Ni, Nb, V, Fe, Mo, Ta, W, Hf, and/or one or more of rare earth metals such as Y, Ce, Gd, Er and/or one or more of another metalloids such as Si, C, B and/or one or more of alkaline earth metals such as Mg, Ca, Sr, Be. In some embodiments, the optically absorbing deep black layer 20 may be, Al—O—N, Al—Si—O—N, Al—Cr—O—N, Al—Ti—O—N, Al—Mg—O—N, Al—Ca—O—N, Al—Mn—O—N, Al—Zn—O—N, Al—Ta—O—N, Al—W—O—N, Al—Mo—O—N, Si—O—N, Si—Mg—O—N, Si—Ca—O—N, Ti—O—N, Nb—Ti—O—N, Ti—Mg—O—N, Ti—Ca—O—N, Ni—O—N, Ni—Ca—O—N, Ni—Mg—O—N.

According to the present invention, the optically absorbing deep black layer 20 may be formed as a gradient layer, having a decreasing concentration of metal and an increasing concentration of oxygen or a combination of oxygen and nitrogen as the distance from the substrate increases. In this regard, the absorbing layer 20 may be a compound of Me₁₋ₓRₓ in which x is preferentially adjusted as follows: 0.05<x<0.5 and R refers to non-metallic elements (can be oxygen or a combination of oxygen and nitrogen), to produce sub-oxides or sub-oxynitrides material to obtain unique absorption behavior. The inventors have surprisingly observed that for the oxynitride optically absorbing deep black layer, the oxygen to nitrogen ratio within the gradient layer should be fixed and at least of a value of 0.4 or above, meaning that oxygen corresponds to 40% of the non-metal elements.

The present invention will now be described with respect to depositing the deep black layer 20 on the substrate 10. FIG. 1 provides a schematic view of a coating chamber that may be used for the present invention. It is contemplated that the optically absorbing deep black layer 20 may be deposited by reactive magnetron sputtering (bipolar, high power impulse magnetron sputtering (HiPIMS), direct current (DC), etc.) in which the discharge voltage is controlled by a feedback control of the reactive gas (oxygen or a combination of oxygen and nitrogen). Indeed, the inventors have surprisingly observed that a smooth and control transition from pure metal to metal oxide (or metal oxynitride) is preferred to achieve the optically absorbing deep black layer. The control of the oxygen to nitrogen ratio in the coating is done by a proper adjustment of the ratio of the reactive gas (here O₂ and N₂) injected in a vacuum chamber via the feedback controller.

It is contemplated that the resulting optically absorbing deep black layer 20 may have a thickness greater than 0.1 μm, preferably greater than 0.3 μm, most preferably greater than 0.5 μm. It is also contemplated that the resulting optically absorbing deep black layer 20 may have a Deep Black value L* between 30 and 40 (according to the CIE 1976 L*a*b* Color Space based on a D65 standard illumination).

According to another embodiment, the present invention may deposit a hard and optically transparent layer 30 directly onto the deep black layer when the deep black layer is directly deposited onto the substrate or it is deposited on a metallic adhesion-promoting layer. The term “optically transparent” means that the material has a high transmission coefficient (close to 100%) for light with energies in the IR, visible and UV wavelength ranges. Similar to the optically absorbing deep black layer 20, the hard and optically transparent layer 30 may include a single metal element, or may be a complex metal oxynitride including a mixture of multiple metals. In some embodiments, the optically absorbing deep black layer 30 may include a two-metal composition (M1_{w}M2ₓO_{y}N_{z}), a three-metal composition (M1ᵥM2_{w}M3ₓO_{y}N_{z}), a four-metal composition (M1ᵤM2ᵥM3_{w}M4ₓO_{y}N_{z}), a five-metal composition (M1ₜM2ᵤM3ᵥM4_{w}M5ₓO_{y}N_{z}), etc. In each of the foregoing optically absorbing deep black layers 30, the variables t, v, w, x, y, z may be positive integers or decimal values.

According to one embodiment, the hard and optically transparent layer 30 may be a monolithic layer, having a constant content in metal and a constant content of oxygen and nitrogen. The content of metal may be between 0.4 to 0.5, the oxygen content may be between 0.05 to 0.1 and the nitrogen may be between 0.4 to 0.45. Surprisingly, the inventor has discovered that the hard and optically transparent layer 30 preferably is oxygen-deficient in comparison to nitrogen in order to produce a hard layer.

Similar to the optically absorbing deep black layer 20, the hard and optically transparent layer 30 may be deposited by reactive magnetron sputtering (bipolar, high power impulse magnetron sputtering (HiPIMS), direct current (DC), etc.). The hard and optically transparent layer 30 may have a thickness greater than 0.3 μm, preferably greater than 0.5 μm, most preferably greater than 1.0 μm. The hard and optically transparent layer 30 may have a minimum preferred hardness that is not less than 12 GPa, preferably not less than 15 GPa, and even more preferably not less than 20 GPa.

The following is one example of coating a substrate with the coatings discussed in detail above.

### EXAMPLE

In the case of this example, an AlON (Aluminium oxynitride) coating was deposited using magnetron reactive sputtering. A metal-based adhesion layer, an optically absorbing deep black layer 20 and the hard and transparent AlON 30 were deposited. The following steps were carried out to create the functional deep black coating:
Step 1: Tungsten carbide (WC) and Alumina (Al2O3) substrates were solvent cleaned and loaded onto a 2-axis of rotation planetary vacuum system.
Step 2: The vacuum chamber was evacuated to the low 10E-5 mbar range.
Step 3: Argon plasma etching of the substrates was done for 10 minutes using a RF substrate biasing.
Step 4: The operating pressure was then adjusted to 5.0E-3 mbar with Argon flow regulated to 250 sccm.
Step 5: Bipolar power was then delivered to an unbalanced 6″ circular planar Aluminum target starting at 5 kW for a duration of 3 minutes in order to create an Aluminum adhesion layer.
Step 6: A closed loop control of the reactive gases O₂ and N₂ was then used to create the optically absorbing deep black layer 20, according to the present invention, using a control of the reactive gas process by a discharge voltage regulation device. The ratio of O₂ to N₂ was set to 0.2:0.8, meaning that in the total flow of reactive gas injected in the vacuum system, 20% corresponds to O 2 and 80% to N₂. The software control of the vacuum system allows the user to program a ramping function while fixing the O₂/N₂ ratio. The reactive gases are then ramped at this set ratio slowly over a period of 20 min. so that the cathode voltage decreases steadily from a pure metal condition to a final set fully oxynitride film. At this point, the O₂/N₂ gas ratio is modified to 0.1:0.9 in order to achieved an optimum chemical stoichiometry of the oxynitride top layer.
Step 7: The conditions are then held at constant until the desired thickness is reached for the hard and transparent top layer 30 of the coating.

The resulting coating was comprised of a pure Aluminum layer of 0.3 μm-thick, an optically absorbing deep black layer 20 of 0.5 μm-thick and a hard and transparent AlON layer 30 of 4.0 μm-thick. The coating characteristic and visual appearance was compared between two coatings using the spectrophotometer Konica-Minolt CN-2600d. The color characteristic of the AlON-based containing the metal-adhesion layer and the optically absorbing deep black layer 30 (see FIG. 2) was L*33, a*−0.84 and b*−0.1 characteristic of a deep black appearance according to the CIE 1976 L*a*b* Color Space. Of note, the coating characteristic is independent of the substrate material demonstrating that the coating appearance can match any kind of substrate material. This may be desirable in the decorative industry.

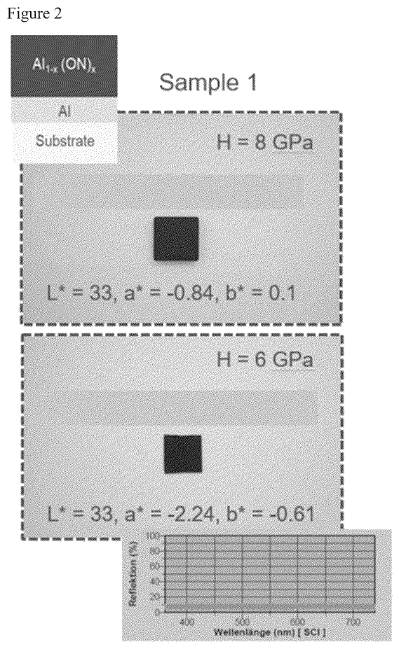

Of note, the color characteristic of the second coating including on top the hard and optically dense layer 30 is similar with a L*35, a*−0.04 and b *−0.75 also characteristic of a deep black appearance according to the CIE 1976 L*a*b* color space. See. FIG. 3. This results from the presence of the anti-reflective and transparent optical functionality of the top layer. The spectrophotometer can also provide the reflection behavior of the two selected coatings as depicted by the reflectivity spectrum vs wavelength in the bottom graphs for FIGS. 2 and 3. It can be seen that the % of the light reflection for both coatings is very low which is also expected from a deep black appeared surface.

Further, a comparison of mechanical properties of the two coatings was performed. While both coatings exhibit the same color appearance the hardness value of the AlON-coating without the hard and transparent top layer 30 is low, less than 10 GPa (see FIG. 2). On the other hand, the addition of the hard and transparent top layer 30 significantly improves the mechanical performance of the coating with a measured hardness 22 GPa (see FIG. 3). In conclusion, the deposition of the top hard and transparent layer 30 did not jeopardize the optical effect of the coating but on the other hand enhance the mechanical performance of the decorative coating.

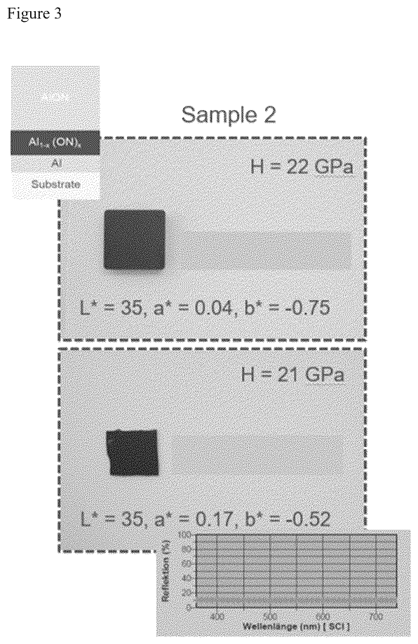

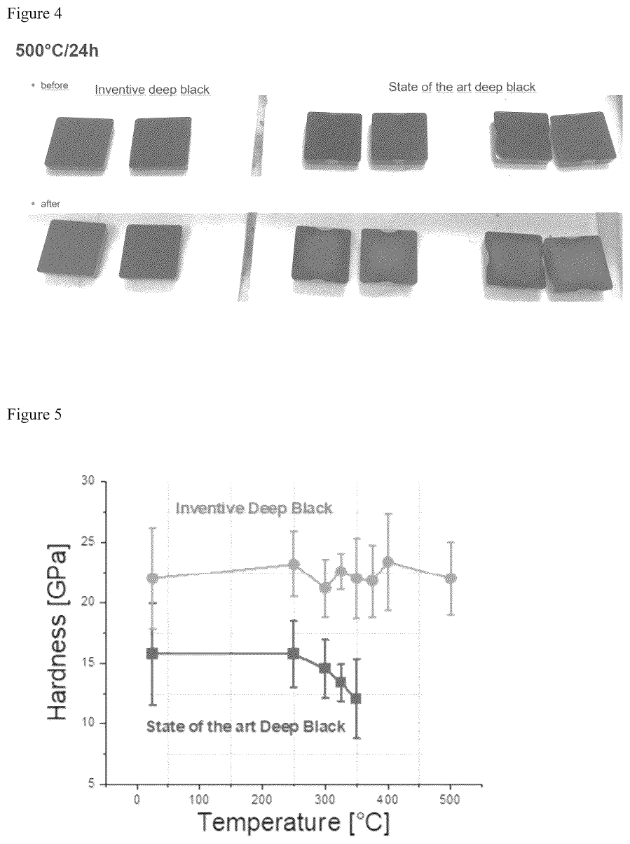

Two selected deep black coatings, respectively a DLC-based and the AlON coating (according to the present invention) were deposited onto cemented carbide and subjected to high temperature annealing at a temperature of 500° C. for 24 hours. See FIGS. 4 and 5. The state of the art DLC deep black peeled off after high temperature exposure leaving the surface exposed to oxidation. No changes were visually or optically observed for the deep black coating of the present invention. The color characteristic remains unaltered with a L* of 35 even after the 24 hours of high temperature exposure.

In addition to the foregoing, the hardness of both coatings were monitored as a function of annealing temperature. For the DLC-based deep black layer according to the known art, a hardness decrease between 250 and 400° C. can be observed, indicating graphitization effect. Above this annealing temperature, the coating peeled off, as previously mentioned. On the other hand, the deep black coating (according to the present invention) exhibited no change in its mechanical properties even at 500° C. with excellent stability of the mechanical properties. The foregoing confirms the enhanced thermal stability of the inventive deep black coating.

The invention has been described with reference to the example embodiments described above. Modifications and alterations will occur to others upon a reading and understanding of this specification. Examples embodiments incorporating one or more aspects of the invention are intended to include all such modifications and alterations insofar as they come within the scope of the appended claims and their equivalents.

1. A coating deposited on a substrate, the coating comprising:
a deep black metal oxide and/or oxynitride layer deposited directly onto the substrate or onto a metallic-adhesion promoting layer
followed by a hard and optically transparent oxynitride layer.

2. The coating according to claim 1, wherein the deep black metal oxide and/or oxynitride layer has a perceptual lightness value L*<40.

3. The coating according to claim 1, wherein the deep black metal oxide and/or oxynitride layer includes one or more metals or one or more rare earth metals or one or more metalloids or one or more alkaline earth metals.

4. The coating according to claim 3, wherein the one or more metals includes AI, Ti, Cr, Ni, Nb, V, Fe, Mo, Ta, W or Hf or the one or more rare earth metals includes Y, Ce, Gd or Er or the one or more metalloids includes Si, C or B or the one or more alkaline earth metals includes Mg, Ca, Sr or Be.

5. The coating according to claim 1, wherein the deep black metal oxide and/or oxynitride layer includes a decreasing concentration of metal and an increasing concentration of oxygen or a combination of oxygen and nitrogen as measured from the substrate.

6. The coating according to claim 5, wherein the deep black metal oxide and/or oxynitride layer is Me₁₋ₓRₓ where 0.05<x<0.5 and R is a non-metallic element that includes oxygen and/or a combination of oxygen and nitrogen.

7. The coating according to claim 5, wherein in the deep black oxynitride layer a ratio of oxygen to nitrogen is fixed and is 0.4 or above.

8. The coating according to claim 1, wherein the deep black metal oxide and/or oxynitride layer has a thickness greater than 0.1 μm.

9. The coating according to claim 1, wherein the deep black metal oxide and/or oxynitride layer has a thickness greater than 0.3 μm.

10. The coating according to claim 1, wherein the deep black metal oxide and/or oxynitride layer has a thickness greater than 0.5 μm.

11. The coating according to claim 1, further comprising:
an optically transparent oxynitride layer deposited on the deep black metal oxide and/or oxynitride layer.

12. The coating according to claim 11, wherein the optically transparent oxynitride layer includes one or more metals or one or more rare earth metals or one or more metalloids or one or more alkaline earth metals.

13. The coating according to claim 12, wherein the one or more metals includes Al, Ti, Cr, Ni, Nb, V, Fe, Mo, Ta, W or Hf or the one or more rare earth metals includes Y, Ce, Gd or Er or the one or more metalloids includes Si, C or B or the one or more alkaline earth metals includes Mg, Ca, Sr or Be.

14. The coating according to claim 11, wherein the optically transparent oxynitride layer is a monolithic layer having a content of metal that is between 0.4 to 0.5, a content of oxygen that is between 0.05 to 0.1 and a content of nitrogen that is between 0.4 to 0.45.

15. The coating according to claim 11, wherein the optically transparent oxynitride layer has a thickness greater than 0.3 μm.

16. The coating according to claim 11, wherein the optically transparent oxynitride layer has a thickness greater than 0.5 μm.

17. The coating according to claim 11, wherein the optically transparent oxynitride layer has a thickness greater than 1.0 μm.

18. The coating according to claim 11, wherein the optically transparent oxynitride layer has a hardness that is greater than 12 Gpa.

19. The coating according to claim 11, wherein the optically transparent oxynitride layer has a hardness that is greater than 15 Gpa.

20. The coating according to claim 11, wherein the optically transparent oxynitride layer has a hardness that is greater than 20 GPa.

21. A process of depositing a deep black coating on a substrate, comprising steps of:
implementing a closed loop control of a reactive gas in a coating chamber to deposit a deep black metal oxide and/or oxynitride layer directly onto the substrate; and
maintaining conditions achieved during the foregoing step for a predetermined period of time to deposit an optically transparent oxynitride layer on the deep black metal oxide and/or oxynitride layer.

22. The process according to claim 21, wherein prior to said step of implementing, comprising steps of:
solvent cleaning the substrate;
placing the substrate in a coating chamber;
evacuating the coating chamber;
plasma etching the substrate; and
exposing the substrate to bipolar power to create an adhesion layer on the substrate.
